(19) United States
(12) Patent Application Publication
(10) Pub. No.: US 2025/0351281 A1
(43) Pub. Date: Nov. 13, 2025

(54) BUSBAR MODULE AND BUSBAR MODULE MANUFACTURING METHOD

(71) Applicant: YAZAKI CORPORATION, Tokyo (JP)

(72) Inventors: Tatsuya Oga, Makinohara-shi (JP); Katsunori Sato, Makinohara-shi (JP); Mariko Nakagawa, Makinohara-shi (JP); Seigo Mochizuki, Fujieda-shi (JP)

(21) Appl. No.: 19/197,975

(22) Filed: May 3, 2025

(30) Foreign Application Priority Data
May 13, 2024 (JP) 2024-078043

(51) Int. Cl. H05K 5/02; H05K 5/00

(52) U.S. Cl. CPC H05K 5/0247; H05K 5/0026

(57) ABSTRACT

A busbar module includes: a flexible printed circuit board including a trunk portion having a longitudinal direction and a width direction and a branch portion connected to an edge of the trunk portion in the width direction; a busbar connected to the branch portion of the flexible printed circuit board; and a case that accommodates the flexible printed circuit board and the busbar. The branch portion is cut into a shape having: a base end connected to the trunk portion; and a piece portion extending from the base end in the longitudinal direction. The branch portion is connected to the busbar in a state where the piece portion is deformed so as to extend in the width direction.

### CROSS-REFERENCE TO RELATED APPLICATION(S)

The present application claims priority to and incorporates by reference the entire contents of Japanese Patent Application No. 2024-078043 filed in Japan on May 13, 2024.

### BACKGROUND OF THE INVENTION

### 1. Field of the Invention

The present invention relates to a busbar module and a busbar module manufacturing method.

### 2. Description of the Related Art

There is a conventional technique of connecting a flexible printed circuit board and a busbar to each other. JP 2023-074 117 A discloses a connection structure between a busbar and a circuit board in which the busbar is connected to a flat plate-like portion of the circuit board. The flat plate-like portion of JP 2023-074 117 A extends in a width direction of the circuit board.

In the circuit board of JP 2023-074 117 A, when the distance from the trunk portion of the circuit board to the busbar is long, the flat plate-like portion needs to be long. This might result in yield deterioration at the time of manufacturing the circuit board. It is desirable to suppress the yield deterioration in the flexible printed circuit board when the branch portion is extended in the width direction between the trunk portion of the flexible printed circuit board and the busbar.

### SUMMARY OF THE INVENTION

An object of the present invention is to provide a busbar module and a busbar module manufacturing method capable of suppressing yield deterioration in a flexible printed circuit board.

In order to achieve the above mentioned object, a busbar module according to one aspect of the present invention includes a flexible printed circuit board including a trunk portion having a longitudinal direction and a width direction and a branch portion connected to an edge of the trunk portion in the width direction; a busbar connected to the branch portion of the flexible printed circuit board; and a case that accommodates the flexible printed circuit board and the busbar, wherein the branch portion is cut into a shape having a base end connected to the trunk portion and a piece portion extending from the base end in the longitudinal direction, and the branch portion is connected to the busbar in a state where the piece portion is deformed so as to extend in the width direction.

In order to achieve the above mentioned object, a busbar module manufacturing method according to another aspect of the present invention includes a step of forming a flexible printed circuit board including a trunk portion having a longitudinal direction and a width direction and a branch portion connected to an edge of the trunk portion in the width direction; a step of deforming the branch portion; a step of connecting a busbar to the branch portion; and a step of accommodating the busbar and the flexible printed circuit board in a case, wherein the step of forming the flexible printed circuit board includes cutting the branch portion into a shape having a base end connected to the trunk portion and a piece portion extending from the base end in the longitudinal direction, and the step of deforming the branch portion includes deforming the branch portion to allow the piece portion to extend in the width direction.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a plan view of a busbar module according to an embodiment;

FIG. 2 is a perspective view of the busbar module according to the embodiment;

FIG. 3 is an arrangement example of a flexible printed circuit board that can be manufactured from one substrate;

FIG. 4 is a perspective view illustrating a state in which a bent portion is formed;

FIG. 5 is a plan view illustrating an example of a jig plate;

FIG. 6 is a view illustrating a flexible printed circuit board placed on a jig plate;

FIG. 7 is a view illustrating a flexible printed circuit board in which a bent portion is formed by a jig plate;

FIG. 8 is a perspective view illustrating an example of a deformation mode of a branch portion;

FIG. 9 is a plan view illustrating an example of a deformation mode of the branch portion;

FIG. 10 is a plan view illustrating an example of the jig plate; and

FIG. 11 is a view illustrating a flexible printed circuit board placed on the jig plate.

### DETAILED DESCRIPTION OF THE PREFERRED EMBODIMENTS

Hereinafter, a busbar module and a busbar module manufacturing method according to an embodiment of the present invention will be described in detail with reference to the drawings. Note that the present invention is not limited by the embodiment. Moreover, components in the following embodiment include those that are easily conceivable for those skilled in the art or substantially identical.

### Embodiment

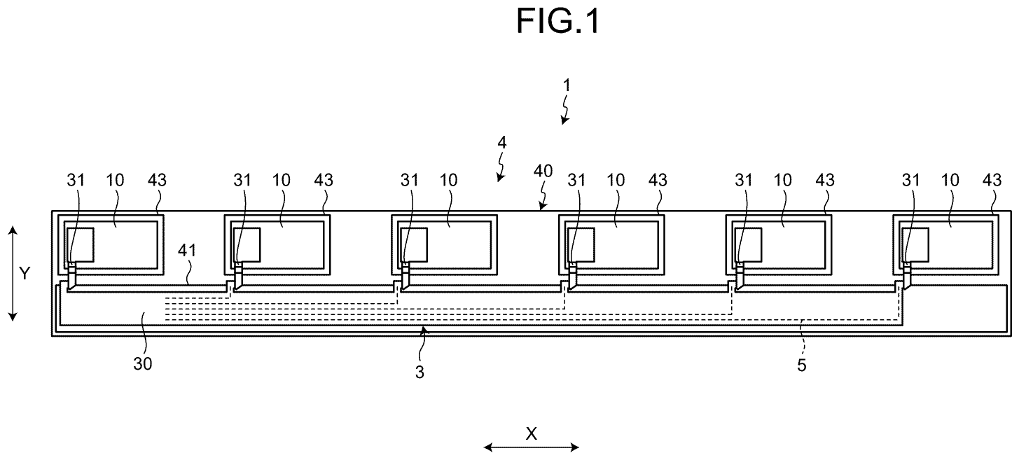

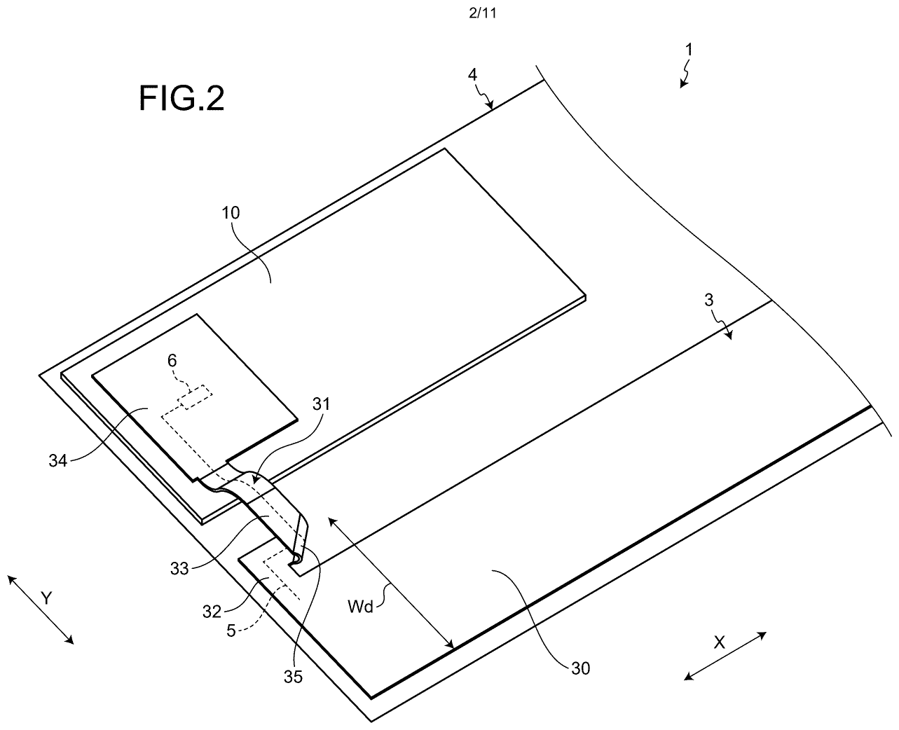

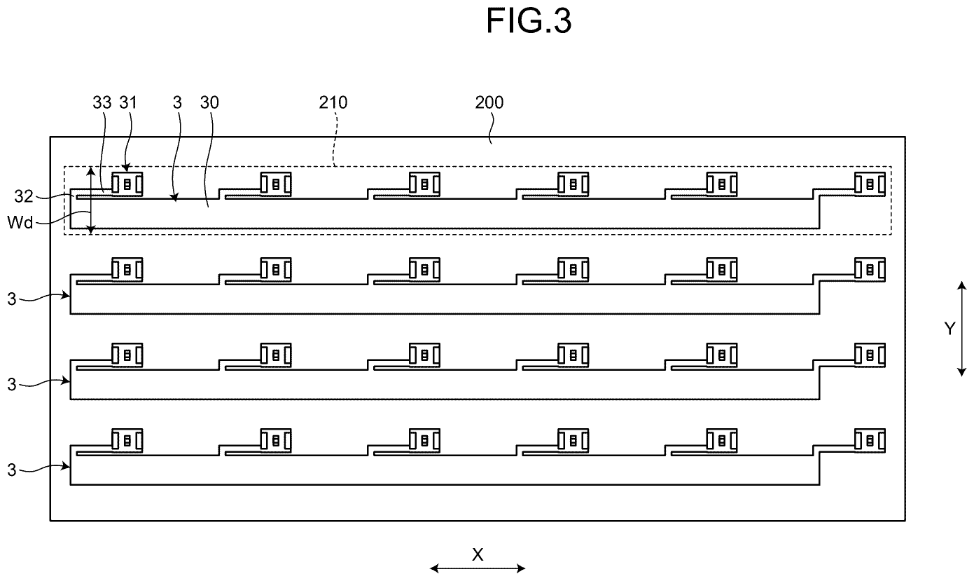

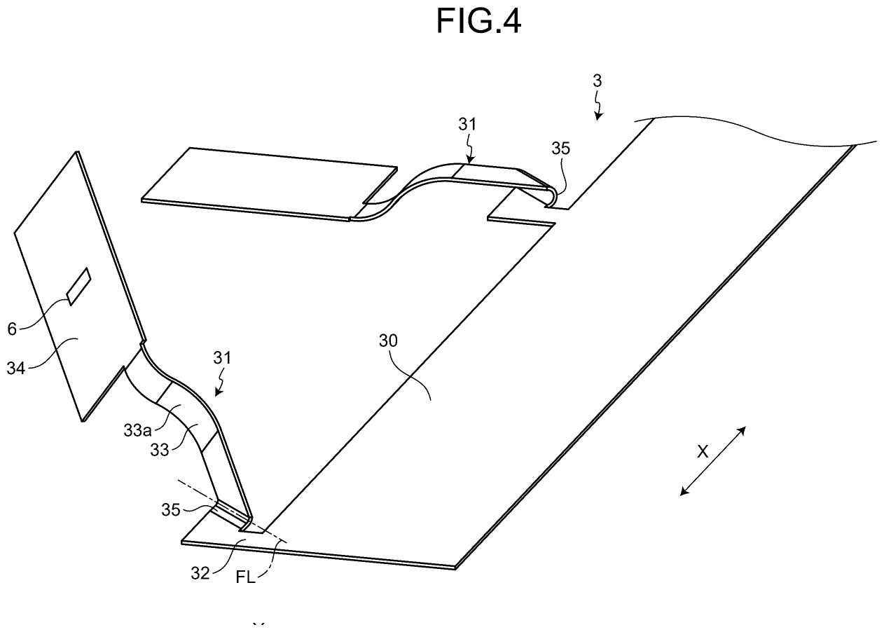

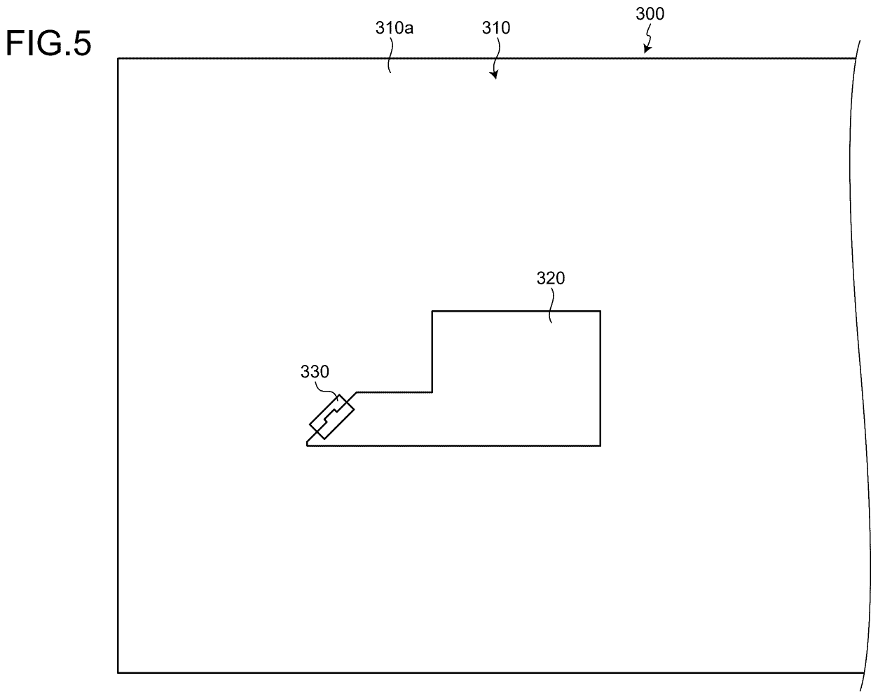

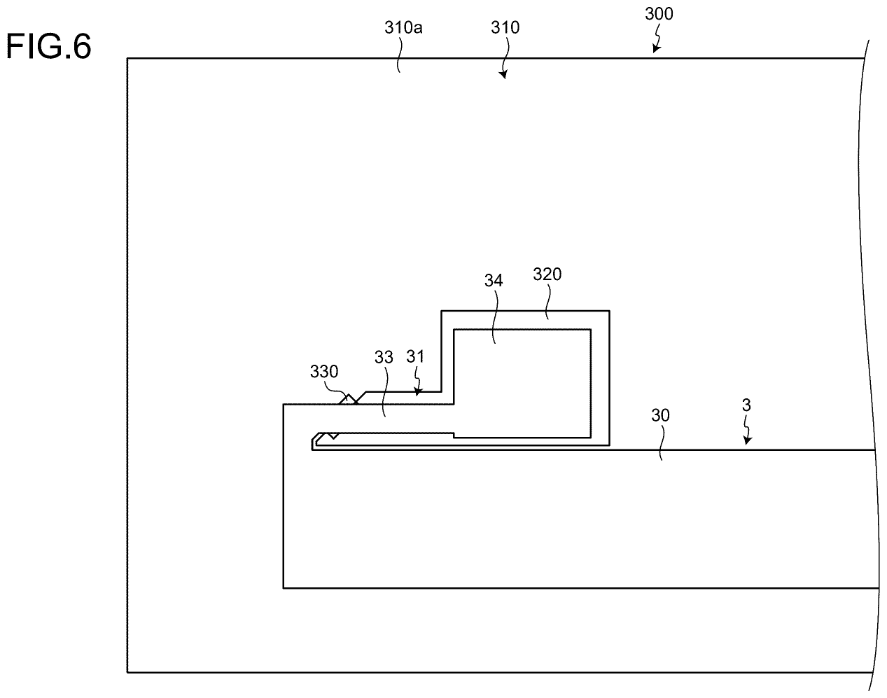

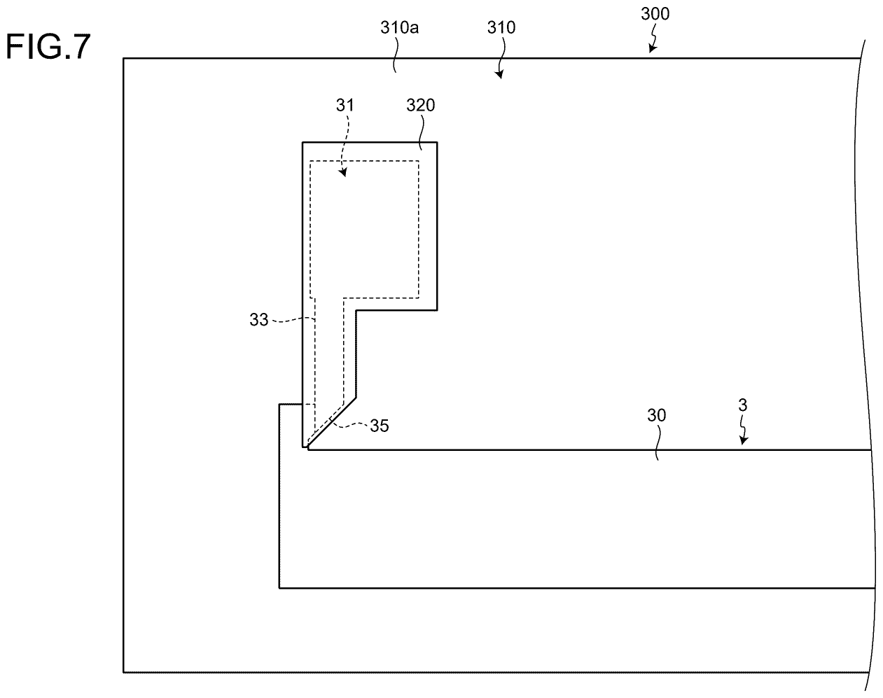

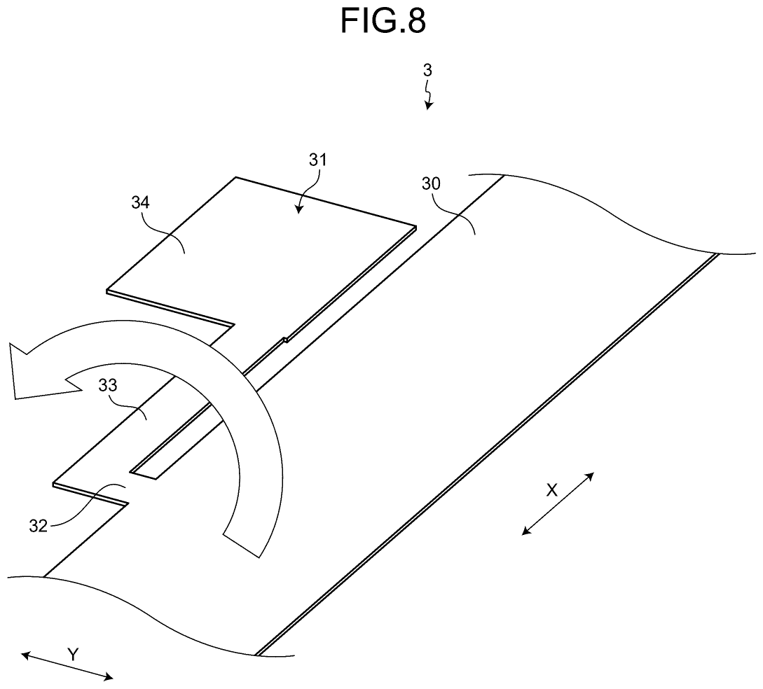

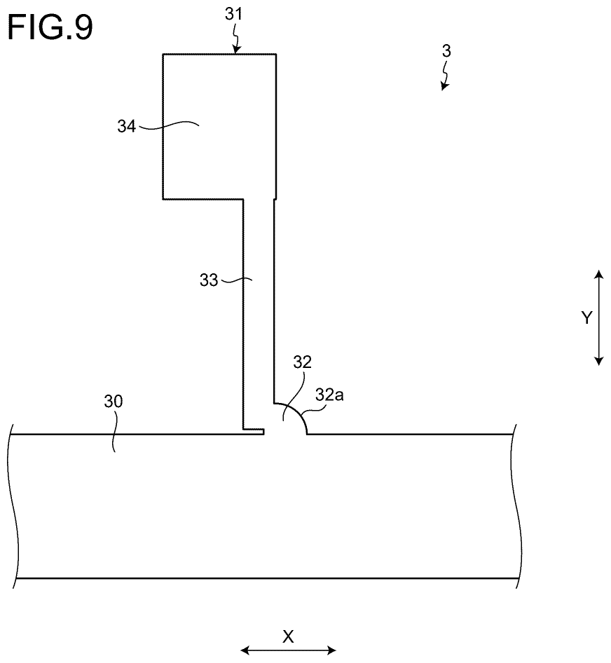

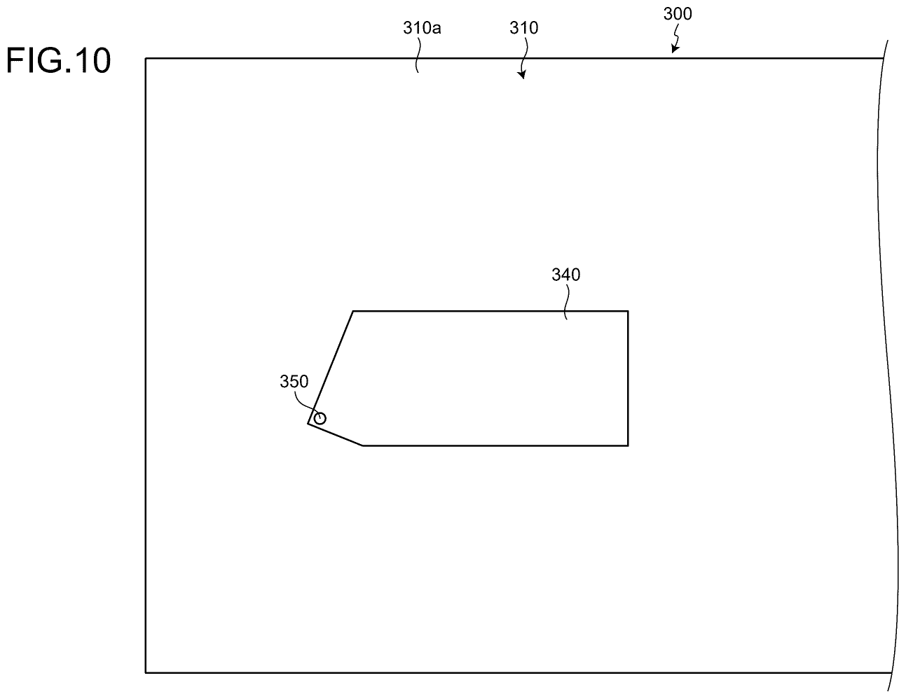

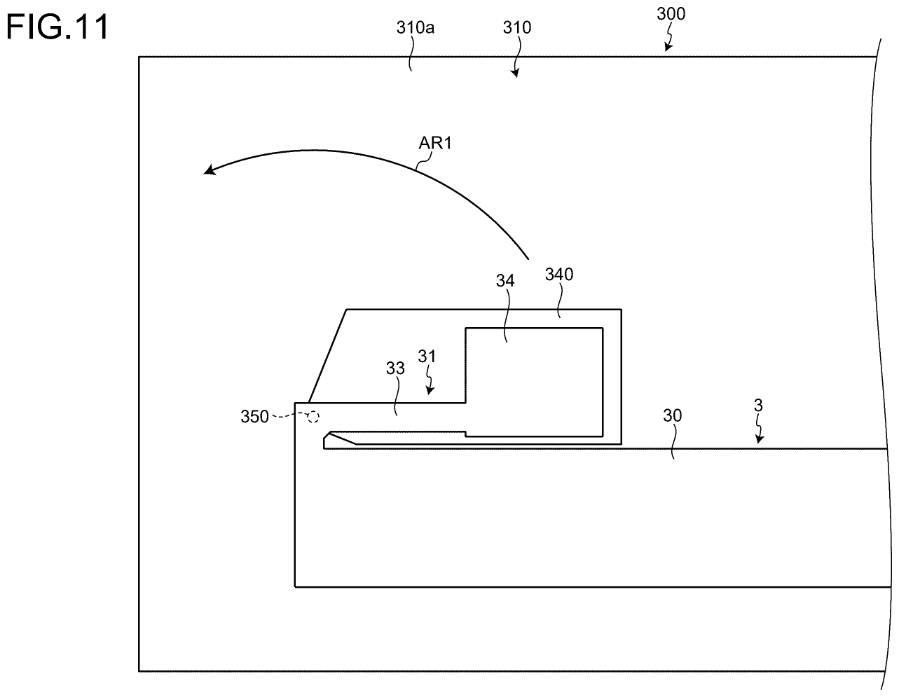

An embodiment will be described with reference to FIGS. 1 to 11. The present embodiment relates to a busbar module and a busbar module manufacturing method. FIG. 1 is a plan view of a busbar module according to the embodiment. FIG. 2 is a perspective view of the busbar module according to the embodiment. FIG. 3 is a perspective view of an arrangement example of a flexible printed circuit board that can be manufactured from one substrate. FIG. 4 is a perspective view illustrating a state in which a bent portion is formed. FIG. 5 is a plan view illustrating an example of a jig plate. FIG. 6 is a view illustrating a flexible printed circuit board placed on the jig plate. FIG. 7 is a view illustrating a flexible printed circuit board in which a bent portion is formed by the jig plate. FIG. 8 is a perspective view illustrating an example of a deformation mode of a branch portion. FIG. 9 is a plan view illustrating an example of a deformation mode of the branch portion. FIG. 10 is a plan view illustrating an example of the jig plate. FIG. 11 is a view illustrating a flexible printed circuit board placed on the jig plate. As illustrated in FIG. 1, a busbar module 1 of the present embodiment includes a flexible printed circuit board 3, a busbar 10, and a case 4. The flexible printed circuit board 3 includes a base film, a coverlay, and a conductive layer. The base film and the coverlay are flexible insulating resin layers. The conductive layer is sandwiched and protected by the base film and the coverlay. The conductive layer is a conductive metal foil, and has a plurality of circuit patterns 5, for example.

The flexible printed circuit board 3 includes a trunk portion 30 and a branch portion 31. The trunk portion 30 has a longitudinal direction X and a width direction Y. The plurality of circuit patterns 5 extends in the longitudinal direction X, and is each arranged in the width direction Y in the trunk portion 30. The branch portion 31 is a portion connected to the busbar 10. The branch portion 31 is connected to an edge of the trunk portion 30 in the width direction Y.

FIG. 2 is an enlarged view of the branch portion 31 connected to the busbar 10. In the busbar module 1 of the present embodiment, the branch portion 31, being in a deformed state, is connected to the busbar 10. More specifically, the branch portion 31 of the present embodiment has a base end 32 and a piece portion 33. The base end 32 is a portion connected to the trunk portion 30. The piece portion 33 is connected to the trunk portion 30 via the base end 32. As illustrated in FIG. 3, the branch portion 31 is cut from the substrate 200 so as to allow the piece portion 33 to extend from the base end 32 in the longitudinal direction X. In other words, when the flexible printed circuit board 3 is formed, the piece portion 33 extends from the base end 32 in the longitudinal direction X.

As illustrated in FIG. 2, there is provided a connecting portion 34 at a tip of the piece portion 33. The connecting portion 34 has a contact portion to be connected to the busbar 10. There is provided a chip fuse 6 mounted on the connecting portion 34. The busbar 10 is connected to the circuit pattern 5 via the chip fuse 6.

The branch portion 31 is connected to the busbar 10 in a state where the piece portion 33 is deformed so as to extend in the width direction Y. The branch portion 31 in FIG. 2 includes a bent portion 35. The bent portion 35 is bent so as to allow the piece portion 33 to extend in the width direction Y. By deforming the branch portion 31, the branch portion 31 can be extended to the busbar 10 in the width direction Y.

According to the busbar module 1 of the present embodiment, suppressing a width Wd of the flexible printed circuit board 3 at the time of manufacturing makes it possible to improve the manufacturing efficiency and reduce the manufacturing cost. For example, the decrease in the width Wd of the flexible printed circuit board 3 leads to an increased number of flexible printed circuit boards 3 that can be formed from the substrate 200 as described below. For example, the decreased width Wd will improve the efficiency of the step of mounting components such as the chip fuse 6 on the flexible printed circuit board 3. FIG. 3 illustrates an arrangement example of the flexible printed circuit board 3 that can be manufactured from one substrate 200. In the example of FIG. 3, four flexible printed circuit boards 3 are formed from one substrate 200. As illustrated in FIG. 3, in the flexible printed circuit board 3 of the present embodiment, the branch portion 31 is cut to allow the piece portion 33 to extend in the longitudinal direction X. This makes it possible to minimize an outermost shape 210 of one flexible printed circuit board 3 in the substrate 200. More specifically, the width Wd of the outermost shape 210 can be shortened.

As a comparative example with respect to the flexible printed circuit board 3 of the present embodiment, a flexible printed circuit board in which the entire branch portion extends in the width direction Y from the trunk portion 30 will be examined. In the flexible printed circuit board of the comparative example, the value of the width Wd is determined according to the distance from the trunk portion 30 to the busbar 10. Therefore, when the distance from the trunk portion 30 to the busbar 10 is long, the width Wd of the outermost shape 210 would increase. As a result, the number of flexible printed circuit board that can be formed from one substrate 200 would be reduced in some cases.

In contrast, the busbar module 1 of the present embodiment can minimize the width Wd of the outermost shape 210 of the flexible printed circuit board 3. For example, the width Wd of the outermost shape 210 can be formed to have a uniform size regardless of the distance from the trunk portion 30 to the busbar 10.

FIG. 4 illustrates the flexible printed circuit board 3 when the bent portion 35 is formed in the branch portion 31. The bent portion 35 is formed, for example, at a root portion of the piece portion 33 close to the base end 32. In the bent portion 35, the piece portion 33 is bent along a folding line FL. The folding line FL is inclined with respect to the longitudinal direction X and the width direction Y. The inclination angle of the folding line FL with respect to the width direction Y is 45°, for example. The piece portion 33 is bent with a mounting surface 33a facing inward, for example. The mounting surface 33a is a surface on which the chip fuse 6 is mounted. The contact portion connected to the busbar 10 is exposed to the mounting surface 33a.

The step of deforming the branch portion 31 may be performed manually by an operator or may be performed using a jig. FIG. 5 illustrates an example of a jig plate 300 used in the bending step. The jig plate 300 includes: a main body 310 having a placement surface 310a; and a support 320 pivotable with respect to the main body 310. The support 320 is connected to the main body 310 via a hinge 330. The hinge 330 has a rotating shaft along the placement surface 310a. The support 320 rotates while supporting the piece portion 33 of the flexible printed circuit board 3.

FIG. 6 illustrates the flexible printed circuit board 3 placed on the jig plate 300. The flexible printed circuit board 3 is set on the jig plate 300 such that the trunk portion 30 is to be placed on the placement surface 310a of the main body 310 and the piece portion 33 is to be placed on the support 320. The support 320 pivots while supporting the piece portion 33, and forms the bent portion 35 in the piece portion 33. FIG. 7 illustrates the flexible printed circuit board 3 in which the bent portion 35 is formed using the jig plate 300.

The connecting portion 34 may be connected to the busbar 10 before the bending step, or may be connected to the busbar 10 after the bending step. When the connecting portion 34 is connected to the busbar 10 before the bending step, the support 320 may be formed so as to be able to support the piece portion 33 and the busbar 10.

The method of manufacturing the busbar module 1 according to the present embodiment includes a forming step, a deforming step, a connecting step, and an accommodating step. The forming step is a step of forming the flexible printed circuit board 3.

The forming step forms the flexible printed circuit board 3 including: the trunk portion 30 having the longitudinal direction X and the width direction Y; and the branch portion 31 connected to the edge of the trunk portion 30 in the width direction Y. The forming step is performed by a device that cuts the flexible printed circuit board 3 from the substrate 200, for example. This device performs punching with a mold to cut out the flexible printed circuit board 3, for example. In the forming step, the branch portion 31 is cut so as to have the base end 32 connected to the trunk portion 30 and to have the piece portion 33 extending from the base end 32 in the longitudinal direction X. The step executed after the forming step is a mounting step of mounting components such as the chip fuse 6 on the flexible printed circuit board 3. The deforming step deforms the branch portion 31 of the flexible printed circuit board 3. In the deforming step, the branch portion 31 is deformed to allow the piece portion 33 to extend in the width direction Y. The deforming step may be performed manually by an operator or may be performed using a jig such as the jig plate 300. The deforming step is a bending step of forming the bent portion 35 on the branch portion 31, for example.

The connecting step connects the busbar 10 to the branch portion 31. The busbar 10 is connected to the contact portion disposed in the connecting portion 34 of the branch portion 31 using a process such as welding and soldering.

The accommodating step accommodates the busbar 10 and the flexible printed circuit board 3 in the case 4. As illustrated in FIG. 1, the case 4 includes a main body 40, which accommodates the busbar 10 and the flexible printed circuit board 3. The main body 40 is formed with an insulating synthetic resin, for example. The main body 40 includes a routing path 41 and a plurality of holders 43.

The routing path 41 accommodates the flexible printed circuit board 3. The routing path 41 may be formed as a groove-like passage. The routing path 41 may include, for example, a main passage accommodating the trunk portion 30 and a branch passage accommodating the branch portion 31.

The holder 43 accommodates and holds the busbar 10. The plurality of holders 43 is adjacent to the routing path 41 in the width direction Y and each arranged in the longitudinal direction X along the routing path 41. The holder 43 is formed in a frame shape and has a projection that locks the busbar 10.

The accommodating step includes: a busbar accommodating step of accommodating the busbar 10 in the holder 43; and a board accommodating step of accommodating the flexible printed circuit board 3 in the routing path 41. The busbar accommodating step and the board accommodating step may be executed simultaneously or may be executed at different timings. For example, the board accommodating step may be executed after completion of the busbar accommodating step, or the busbar accommodating step may be executed after completion of the board accommodating step.

The order of the deforming step, the connecting step, and the accommodating step can be determined to be any order. For example, the deforming step of deforming the branch portion 31 may be executed before the connecting step or may be executed after the connecting step. For example, the flexible printed circuit board 3 in which the bent portion 35 is formed may be accommodated in the case 4 in which the busbar 10 is accommodated. In this case, the connecting portion 34 of the flexible printed circuit board 3 may be connected to the busbar 10 accommodated in the holder 43.

The deformation of the branch portion 31 in the deforming step may be a deformation different from the deformation to form the bent portion 35. For example, as illustrated in FIGS. 8 and 9, the branch portion 31 may be deformed by rotating the piece portion 33 relative to the trunk portion 30. This deformation is deformation in which the base end 32 is deformed to rotate the piece portion 33 relative to the trunk portion 30. The rotating direction of the relative rotation at this time is a rotating direction along a plane including the trunk portion 30. The piece portion 33 rotates relative to the trunk portion 30 about the base end 32. The base end 32 is elastically deformed so as to extend an inner side 32a.

In the branch portion 31 after the deformation, as illustrated in FIG. 9, the piece portion 33 extends in the width direction Y. The deforming step illustrated in FIGS. 8 and 9 may be performed manually by an operator or may be performed using a jig. FIG. 10 illustrates an example of the jig plate 300 used in a rotating step of rotating the piece portion 33. The jig plate 300 in FIG. 10 includes: a main body 310 having a placement surface 310a; and a rotating plate 340 rotatable with respect to the main body 310. The rotating plate 340 rotates about a rotating shaft 350. The axis of the rotating shaft 350 is orthogonal to the placement surface 310a. The rotating plate 340 can rotate along the placement surface 310a about the rotating shaft 350 as a rotation center. The main body 310 may have a stopper to restrict a rotatable range of the rotating plate 340.

FIG. 11 illustrates the flexible printed circuit board 3 placed on the jig plate 300. The flexible printed circuit board 3 is set on the jig plate 300 such that the trunk portion 30 is placed on the placement surface 310a of the main body 310 and the piece portion 33 is placed on the rotating plate 340. The rotating plate 340 may have a holding mechanism that holds the piece portion 33. The rotating plate 340 rotates as indicated by an arrow AR1 while supporting the piece portion 33 so as to allow the piece portion 33 to rotate relative to the trunk portion 30. This allows the branch portion 31 to have a shape in which the piece portion 33 extends in the width direction Y as illustrated in FIG. 9.

The connecting portion 34 may be connected to the busbar 10 before the rotating step, or may be connected to the busbar 10 after the rotating step. In a case where the connecting portion 34 is connected to the busbar 10 before the rotating step, the rotating plate 340 may be formed to be able to hold the piece portion 33 and the busbar 10.

The jig plate 300 used in the rotating step is preferably configured to be able to reduce the load on the circuit pattern 5 due to deformation of the branch portion 31. For example, the position of the rotating shaft 350 of the jig plate 300 may be set so as to reduce the amount of expansion and contraction of the circuit pattern 5 when the piece portion 33 is rotated. As an example, as illustrated in FIG. 11, in a state where the flexible printed circuit board 3 is placed on the jig plate 300, the rotating shaft 350 may be disposed to allow the axis of the rotating shaft 350 to intersect the circuit pattern 5 of the branch portion 31.

As described above, the busbar module 1 of the present embodiment includes the flexible printed circuit board 3, the busbar 10, and the case 4. The flexible printed circuit board 3 includes: the trunk portion 30 having the longitudinal direction X and the width direction Y; and the branch portion 31 connected to the edge of the trunk portion 30 in the width direction Y. The busbar 10 is connected to the branch portion 31 of the flexible printed circuit board 3. The case 4 accommodates the flexible printed circuit board 3 and the busbar 10.

The branch portion 31 is cut so as to have the base end 32 connected to the trunk portion 30 and to have the piece portion 33 extending from the base end 32 in the longitudinal direction X. The branch portion 31 is connected to the busbar 10 in a state where the piece portion 33 is deformed so as to extend in the width direction Y. The busbar module 1 of the present embodiment has a configuration in which the branch portion 31 extends in the width direction Y between the trunk portion 30 and the busbar 10, making it possible to suppress yield deterioration in forming the flexible printed circuit board 3 from the substrate 200.

The branch portion 31 after deformation has, for example, the bent portion 35 in which the piece portion 33 is bent so as to extend in the width direction Y. The position and shape of the bent portion 35 can be adjusted according to the relative position between the trunk portion 30 and the busbar 10. That is, the busbar module 1 of the present embodiment can connect the branch portions 31 to the busbars 10 of various arrangements without changing the design of the flexible printed circuit board 3.

The branch portion 31 may be connected to the busbar 10 in a state where the piece portion 33 is rotated relative to the trunk portion 30 by deforming the base end 32.

The method of manufacturing the busbar module 1 according to the present embodiment includes the above-described forming step, the deforming step, the connecting step, and the accommodating step. In the forming step, the branch portion 31 is cut into a shape having the base end 32 connected to the trunk portion 30 and having the piece portion 33 extending from the base end 32 in the longitudinal direction X. In the deforming step, the branch portion 31 is deformed to allow the piece portion 33 to extend in the width direction Y. According to the method of manufacturing the busbar module 1 according to the present embodiment, it is possible to extend the branch portion 31 in the width direction Y between the trunk portion 30 and the busbar 10 while improving the yield in the forming step.

The mode of deformation of the branch portion 31 by the deforming step is not limited to the mode exemplified in the present embodiment. One flexible printed circuit board 3 may have branch portions 31 each deformed into different shapes. For example, in the plurality of branch portions 31 of the flexible printed circuit board 3, some of the branch portions 31 may be deformed so as to have the bent portion 35, and the other branch portions 31 may be deformed so as to rotate the piece portion 33 relative to the trunk portion 30.

The contents disclosed in the above embodiment can be executed in appropriate combination with each other.

In the busbar module according to the present embodiment, the branch portion of the flexible printed circuit board is cut into a shape including: a base end connected to the trunk portion; and a piece portion extending in a longitudinal direction from the base end, and the branch portion is connected to the busbar in a state where the piece portion is deformed so as to extend in the width direction. According to the busbar module of the present embodiment, it is possible to have an effect of suppressing yield deterioration in the flexible printed circuit board.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A busbar module comprising:
a flexible printed circuit board including a trunk portion having a longitudinal direction and a width direction and a branch portion connected to an edge of the trunk portion in the width direction;
a busbar connected to the branch portion of the flexible printed circuit board; and
a case that accommodates the flexible printed circuit board and the busbar, wherein
the branch portion is cut into a shape having a base end connected to the trunk portion and a piece portion extending from the base end in the longitudinal direction, and
the branch portion is connected to the busbar in a state where the piece portion is deformed so as to extend in the width direction.

2. The busbar module according to claim 1, wherein
the branch portion includes a bent portion bent to allow the piece portion to extend in the width direction.

3. The busbar module according to claim 1, wherein
the branch portion is connected to the busbar in a state where the piece portion is rotated relative to the trunk portion by deforming the base end.

4. A busbar module manufacturing method, the method comprising:
a step of forming a flexible printed circuit board including a trunk portion having a longitudinal direction and a width direction and a branch portion connected to an edge of the trunk portion in the width direction;
a step of deforming the branch portion;
a step of connecting a busbar to the branch portion; and
a step of accommodating the busbar and the flexible printed circuit board in a case, wherein
the step of forming the flexible printed circuit board includes cutting the branch portion into a shape having a base end connected to the trunk portion and a piece portion extending from the base end in the longitudinal direction, and
the step of deforming the branch portion includes deforming the branch portion to allow the piece portion to extend in the width direction.
